(19) United States
(12) Patent Application Publication
(10) Pub. No.: US 2022/0412926 A1
(43) Pub. Date: Dec. 29, 2022

(54) AI METHOD AND APPARATUS FOR EXTRACTING CRACK LENGTH FROM HIGH-FREQUENCY AE (ACOUSTIC EMISSION)

(71) Applicant: UNIVERSITY OF SOUTH CAROLINA, Columbia, SC (US)

(72) Inventors: VICTOR GIURGIUTIU, COLUMBIA, SC (US); HANFEI MEI, COLUMBIA, SC (US); JOSEPH GARRETT, CHARLESTON, SC (US); KIMBERLY CARDILLO, DENVER, CO (US)

(21) Appl. No.: 17/689,557

(22) Filed: Mar. 8, 2022

Related U.S. Application Data
(60) Provisional application No. 63/279,749, filed on Nov. 16, 2021.
(60) Provisional application No. 63/187,637, filed on May 12, 2021.

(51) Int. Cl. G01N 29/44; G01N 29/14; G01N 29/12; G06N 3/04; G06N 3/08; G06F 30/23; G06F 30/27

(52) U.S. Cl. CPC G01N 29/4481; G01N 29/4472; G01N 29/14; G01N 29/12; G06N 3/04; G06N 3/084; G06F 30/23; G06F 30/27; G01N 2291/0289

(57) ABSTRACT

Method and apparatus estimate the length of a fatigue crack in sheet metal structures from individual acoustic emission (AE) signals without recourse to the AE signal history or AE signal amplitude. AE energy generated at one crack tip travels to the other tip and establishes a standing wave pattern that has a characteristic dominant frequency which depends on the crack length. Therefore, crack length information can be recovered from the analysis of the standing wave frequency present in the high-frequency AE signals. We found that the AE signals predicted through numerical simulation have embedded in the high-frequency information that can be related directly to crack size. This information is manifested as peaks in the frequency spectrum that shift as crack length changes. The predictive AE models were tuned against experimentally observed AE signals and a methodology for predicting crack length from AE signals was established. This methodology was utilized to develop machine learning algorithms for predicting crack length directly from individual AE signals. Specific artificial intelligence methodology presently disclosed can estimate in real-time the crack length information from the high-frequency AE waveforms during fatigue crack growth.

### CROSS REFERENCE TO RELATED APPLICATION

This application claims filing benefit of U.S. Provisional Patent Application Ser. No. 63/187,637, having a filing date of May 12, 2021, entitled “AI Method-Apparatus for Extracting Crack Length from High-Frequency AE Signals;” and claims filing benefit of U.S. Provisional Patent Application Ser. No. 63/279,749, having a filing date of Nov. 16, 2021, entitled “AI Method and Apparatus for Extracting Crack Length from High-Frequency AE (Acoustic Emission),” both of which are fully incorporated herein by reference and for all purposes.

### STATEMENT REGARDING FEDERALLY SPONSORED RESEARCH OR DEVELOPMENT

This invention was made with government support under Grant Nos. N00014-17-1-2829 and N00014-21-1-2212, both awarded by the Office of Naval Research. The government has certain rights in the invention.

### BACKGROUND

The presently disclosed subject matter deals with a system and method for extracting crack length from high-frequency Acoustic Emission (AE).

The AE technique has been used for damage detection and source localization of fatigue crack growth in metallic structures. The AE method is a passive, wave propagation-based structural health monitoring (SHM) method for in-situ monitoring. AE is well established as a nondestructive evaluation for monitoring the structural health by listening to the “pops” or “hits” generated by the energy released by an incremental crack growth. The fatigue crack growth in metallic structures generates AE signals due to the formation of the crack. The study of AE during a fatigue crack growth event has attracted many researchers over time. Many researchers have studied the AE due to fatigue crack growth as well as wave scattering from fatigue cracks^{[1]-[6]}. Zhang et al. ^{[7]} studied the acoustic emission signatures of fatigue damages in an idealized bevel gear spline and identified two different AE signal signatures for plastic deformation and crack jump. Bhuiyan et al. ^{[8]-[10]} studied the AE signal signatures recorded by piezoelectric wafer active sensor (PWAS) transducers during a fatigue crack growth experiment in thin metallic plates. In this research, under a slow frequency of fatigue loading (<0.25 Hz), for a short advancement of crack length, the AE signals were recorded, and eight signal signatures related to crack growth and crack rubbing and clapping were discovered.

However, not much research was performed regarding the correlation between the crack length and the AE signal signatures. The exact quantification of the crack length is very important for scheduling the maintenance of the structure in which the crack growth is happening. In the presently disclosed research, a novel method and apparatus is presented to estimate the length of a fatigue crack in sheet metal structures from individual AE signals without recourse to the AE signal history or AE signal amplitude.

The growing number of aging engineering structures and the variable working conditions demand more from the scientific community for a staunch and scrupulous technology for health monitoring purposes. AE is a well-known SHM and nondestructive testing (NDT) technique. The AE analysis method has been used for passive sensing of acoustic signals during a damaging process. The damage process can be impact damage, fatigue crack growth, plastic deformation, etc. in metallic structures, where fatigue crack growth is a common problem. The severity of the occurrence of fatigue crack growth increases with the aging of the metallic structures. However, the current AE practice does not possess an early warning capability because AE hit rates accelerate only when failure is imminent. An early warning capability, if existed, would greatly assist the effective management of structural fatigue in coordination with mission profile allocation and maintenance schedule.

### SUMMARY

The presently disclosed subject matter deals with a system and method for extracting crack length from high-frequency AE.

This presently disclosed subject matter entails three significant features:
1) Predictive modeling of AE signals from fatigue crack growth;
2) Fatigue crack AE experimental validation; and
3) Artificial intelligence (AI)-enabled crack length estimation from AE signals.

Method and apparatus estimate the length of a fatigue crack in sheet metal structures from individual AE signals without recourse to the AE signal history or AE signal amplitude. AE energy generated at one crack tip travels to the other tip and establishes a standing wave pattern that has a characteristic dominant frequency which depends on the crack length. Therefore, crack length information can be recovered from the analysis of the standing wave frequency present in the high-frequency AE signals.

We found that the AE signals predicted through numerical simulation have embedded in the high-frequency information that can be related directly to crack size. This information is manifested as peaks in the frequency spectrum that shift as crack length changes. The predictive AE models were tuned against experimentally observed AE signals and a methodology for predicting crack length from AE signals was established. This methodology was utilized to develop machine learning algorithms for predicting crack length directly from individual AE signals. Specific AI methodology presently disclosed can estimate in real-time the crack length information from the high-frequency AE waveforms during fatigue crack growth.

The presently disclosed subject matter has the capability to estimate fatigue crack length in sheet metal structures using the information contained in the high-frequency AE signal signatures. Physics-based modeling validated by carefully conducted experiments may be utilized to generate synthetic datasets for training AI algorithms. Machine-learning AI-enabled techniques may be used to sift through large experimental AE signal datasets to identify dominant trends correlated with crack length information.

The presently disclosed subject matter has the capability to achieve rapid, remote, and real-time monitoring of fatigue crack growth in sheet metal structures. It can identify the AE signals due to crack growth and discard the AE signals not related to crack growth. It can extract crack length information from the individual AE signals. It can also use the AE signals to monitor crack growth and predict remaining useful life.

Presently disclosed method and apparatus can estimate the length of a fatigue crack in sheet metal structures from individual AE signals. It can obtain a crack length estimation from every AE signal without recourse to the AE-signal history. It can also obtain a crack length estimation from every AE signal without recourse to AE signal power or amplitude.

The presently disclosed subject matter can also process the high-frequency information contained in an AE signal to extract crack length information. It can achieve adaptation of the three-dimensional (3D) moment-tensor concept from geophysics to apply to the prediction of AE signals in thin plates using guided wave theory. Prediction can further be achieved of how crack length values affect the high-frequency content of AE signals as resulting from finite element modeling using the moment tensor concept.

Tuning of predictive AE models can also be achieved to obtain similarity to experimentally observed AE signals.

Selection of representative AE signal features may be made in time domain and frequency domain to enable tuning of the predictive AE models.

As noted by the presently disclosed subject matter, AE energy generated at one crack tip travels to the other tip and establishes a standing wave pattern that has a characteristic dominant frequency which depends on the crack length. Then, per present disclosure, crack length information can be recovered from the analysis of the standing wave frequency present in the high-frequency AE signals.

Use of the specific AI methodology described in this disclosure can estimate in real-time the crack length information from the high-frequency AE waveforms during fatigue crack growth.

It is to be understood that the presently disclosed subject matter equally relates to associated and/or corresponding methodologies. One exemplary such method relates to a computer-implemented method, comprising obtaining, by a computing system comprising one or more computing devices, detected AE data from sensors used with an associated structure to be monitored; inputting, by the computing system, the detected AE data into a machine-learned neural network architecture model configured to receive AE data sensed from a structure and to predictively model SHM of the structure; receiving, by the computing system, as an output of the machine-learned neural network architecture model, a characteristic dominant frequency of a standing wave pattern resulting from AE energy generated at one crack tip and traveling to the other crack tip of a crack formed in the monitored structure; and determining, by the computing system, the crack length of the crack generating the AE data.

Other example aspects of the present disclosure are directed to systems, apparatus, tangible, non-transitory computer-readable media, user interfaces, memory devices, and electronic devices for high-frequency AE processing. To implement methodology and technology herewith, one or more processors may be provided, programmed to perform the steps and functions as called for by the presently disclosed subject matter, as will be understood by those of ordinary skill in the art.

Another exemplary embodiment of presently disclosed subject matter relates to a computing system, comprising one or more processors; and one or more non-transitory computer-readable media that collectively store: a machine-learned AI-enabled technology neural network architecture model configured to receive AE data sensed from a structure and to predictively model SHM of the structure; and instructions that, when executed by the one or more processors, configure the computing system to perform operations, the operations comprising: obtaining detected AE data from sensors used with an associated structure to be monitored; inputting the AE data into the machine-learned neural network architecture model; determining a characteristic dominant frequency of a standing wave pattern resulting from AE energy generated at one crack tip and traveling to the other crack tip of a crack formed in the monitored structure; and as an output of the machine-learned neural network architecture model, determining the crack length of the crack generating the AE data.

Additional objects and advantages of the presently disclosed subject matter are set forth in, or will be apparent to, those of ordinary skill in the art from the detailed description herein. Also, it should be further appreciated that modifications and variations to the specifically illustrated, referred and discussed features, elements, and steps hereof may be practiced in various embodiments, uses, and practices of the presently disclosed subject matter without departing from the spirit and scope of the subject matter. Variations may include, but are not limited to, substitution of equivalent means, features, or steps for those illustrated, referenced, or discussed, and the functional, operational, or positional reversal of various parts, features, steps, or the like.

Still further, it is to be understood that different embodiments, as well as different presently preferred embodiments, of the presently disclosed subject matter may include various combinations or configurations of presently disclosed features, steps, or elements, or their equivalents (including combinations of features, parts, or steps or configurations thereof not expressly shown in the figures or stated in the detailed description of such figures). Additional embodiments of the presently disclosed subject matter, not necessarily expressed in the summarized section, may include and incorporate various combinations of aspects of features, components, or steps referenced in the summarized objects above, and/or other features, components, or steps as otherwise discussed in this application. Those of ordinary skill in the art will better appreciate the features and aspects of such embodiments, and others, upon review of the remainder of the specification, and will appreciate that the presently disclosed subject matter applies equally to corresponding methodologies as associated with practice of any of the present exemplary devices, and vice versa.

These and other features, aspects, and advantages of various embodiments will become better understood with reference to the following description and appended claims. The accompanying figures, which are incorporated in and constitute a part of this specification, illustrate embodiments of the present disclosure and, together with the description, serve to explain the related principles.

### BRIEF DESCRIPTION OF THE FIGURES

A full and enabling disclosure of the present subject matter, including the best mode thereof to one of ordinary skill in the art, is set forth more particularly in the remainder of the specification, including reference to the accompanying figures in which:

FIG. 1 illustrates a schematic of simplified finite element method (FEM) model using the symmetric boundary condition for the AE simulation (with a symmetric boundary condition applied as presented);

FIG. 2A represents, for an M₁₁ moment tensor excitation applied at a crack tip as the crack growth excitation, the top view of the M₁₁ moment excitation generated using dipole forces (F1);

FIG. 2B represents a thickness view of the M₁₁ moment excitation associated with FIG. 2A;

FIG. 2C illustrates waveform of smooth-step excitation;

FIG. 2D illustrates frequency spectrum of such smooth-step excitation associated with FIG. 2C;

FIGS. 3A and 3B illustrate a wave propagation pattern of surface strain (εₓₓ and ε_{yy}) due to M₁₁ excitation, with FIG. 3A representing no crack, and FIG. 3B representing 8 mm crack;

FIGS. 4A through 4D illustrate FEM simulation AE signals of no-crack case, with FIG. 4A illustrating nodal in-plane strain response of AE signal at PWAS sensor center, with FIG. 4B illustrating frequency spectrum of nodal in-plane strain response at PWAS sensor center, with FIG. 4C illustrating 7 mm PWAS response of AE signal at 25 mm from origin, and with FIG. 4D illustrating frequency spectrum of 7 mm PWAS response of AE signal at 25 mm from origin;

FIGS. 5A through 5D illustrate FEM simulation AE signal of 4 mm crack case, with FIG. 5A illustrating nodal in-plane strain response of AE signal at PWAS sensor center, with FIG. 5B illustrating frequency spectrum of nodal in-plane strain response, with FIG. 5C illustrating 7 mm PWAS response of AE signal at 25 mm from crack center, and with FIG. 5D illustrating frequency spectrum of 7 mm PWAS response;

FIGS. 6A through 6D illustrate FEM simulation AE signal of 6 mm crack case, with FIG. 6A illustrating nodal in-plane strain response of AE signal at PWAS sensor center, with FIG. 6B illustrating frequency spectrum of nodal in-plane strain response, with FIG. 6C illustrating 7 mm PWAS response of AE signal at 25 mm from crack center, and with FIG. 6D illustrating frequency spectrum of 7 mm PWAS response;

FIGS. 7A through 7D illustrate FEM simulation AE signal of 8 mm crack case, with FIG. 7A illustrating nodal in-plane strain response of AE signal at PWAS sensor center, with FIG. 7B illustrating frequency spectrum of nodal in-plane strain response, with FIG. 7C illustrating 7 mm PWAS response of AE signal at 25 mm from crack center, and with FIG. 7D illustrating frequency spectrum of 7 mm PWAS response;

FIGS. 8A through 8D illustrate spectrum of AE signals in 1 mm aluminum plate with various crack lengths, with FIG. 8A illustrating no crack, with FIG. 8B illustrating with 4 mm crack, with FIG. 8C illustrating with 6 mm crack, and with FIG. 8D illustrating with 8 mm crack (and for all with the frequency of spectrum peaks directly related to crack length);

FIGS. 9A through 9C illustrate wavefields at various peak frequencies for 8 mm crack response, including at 432.5 kHz (FIG. 9A), 800 kHz (FIG. 9B), and 1188 kHz (FIG. 9C);

FIG. 10 illustrates an AE test specimen bonded with the two PWASs and two S9225 sensors (with non-reflective clay boundaries (NRB) provided on the specimen to avoid the reflection of AE signals from the specimen boundaries);

FIG. 11A illustrates a schematic of an experimental/demonstration setup for performing fatigue testing with AE capturing;

FIG. 11B illustrates equipment and connections for an experimental/demonstration setup for performing fatigue testing with AE capturing, as schematically illustrated in FIG. 11A;

FIGS. 12A and 12B illustrate a comparison between FEM simulation results of crack related AE signals (FIG. 12A) vs. experimental AE Choi-William transform (CWT) plots captured in stress intensity factor (SIF)-controlled fatigue scenario (FIG. 12B);

FIGS. 13A and 13B illustrate a comparison between FEM simulation results of crack related AE signals (FIG. 13A) vs. experimental AE waveforms captured in SIF-controlled fatigue scenario (FIG. 13B);

FIG. 14 illustrates a schematic of a multilayer perception artificial neural network model as presently referenced;

FIG. 15 illustrates a CWT of the acoustic emission signals cropped and augmented to fit the 227×227-pixel criteria before being entered into the input layer of the AlexNet convolutional neural network (CNN) architecture;

FIG. 16 illustrates a schematic of signals from different crack lengths usable to train AlexNet CNN for crack length recognition;

FIG. 17 illustrates example CWT figures used in crack length recognition AlexNet CNN;

FIG. 18 illustrates training progress of crack length recognition AlexNet CNN; and

FIGS. 19A and 19B illustrate manual network test results showing a 98.8% classification accuracy (FIG. 19A) and noisy misclassified AE hit #114 from 44-48 fatigue kilocycles (FIG. 19B).

Repeat use of reference characters in the present specification and drawings is intended to represent the same or analogous features, elements, or steps of the presently disclosed subject matter.

### DETAILED DESCRIPTION

Reference will now be made in detail to various embodiments of the disclosed subject matter, one or more examples of which are set forth below. Each embodiment is provided by way of explanation of the subject matter, not limitation thereof. In fact, it will be apparent to those skilled in the art that various modifications and variations may be made in the present disclosure without departing from the scope or spirit of the subject matter. For instance, features illustrated or described as part of one embodiment, may be used in another embodiment to yield a still further embodiment.

The following description and other modifications and variations to the presently disclosed subject matter may be practiced by those of ordinary skill in the art, without departing from the spirit and scope of the presently disclosed subject matter. In addition, it should be understood that aspects of the various embodiments may be interchanged either in whole or in part. Furthermore, those of ordinary skill in the art will appreciate that the following description is by way of example only and is not intended to limit the presently disclosed subject matter.

This presently disclosed subject matter entails three significant features:
1) Predictive modeling of AE signals from fatigue crack growth;
2) Fatigue crack AE experimental validation; and
3) Artificial intelligence (AI)-enabled crack length estimation from AE signals.

### Example 1

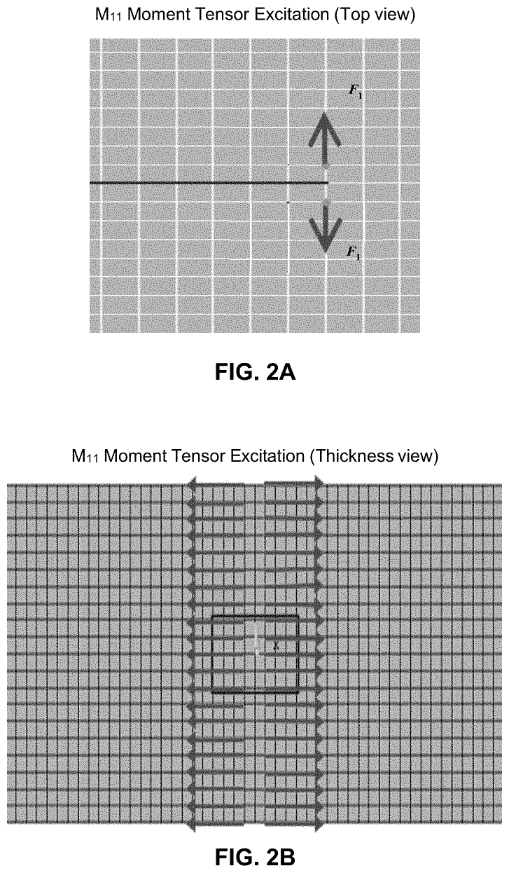

FEM simulation was conducted to identify the correlation between AE signal and crack length during a fatigue crack growth event. A 120-mm length, 60-mm width, and 1-mm thick 3D model was developed using the ANSYS® software package (FIGS. 2A-2D).

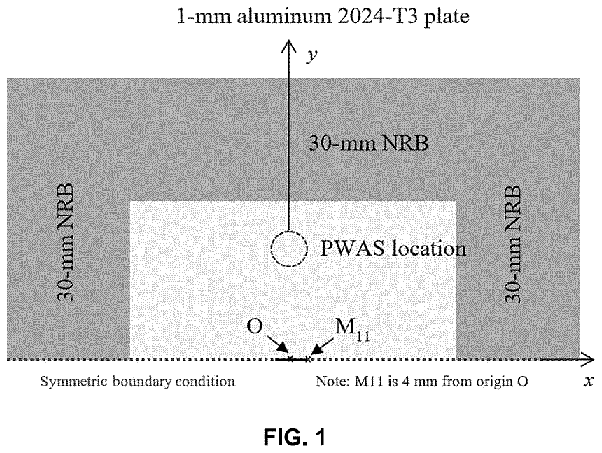

FIG. 1 illustrates a schematic of simplified FEM model using the symmetric boundary condition for the AE simulation (with a symmetric boundary condition applied as presented).

In the FEM simulation, only half the model was given because the symmetric boundary condition was used to reduce the computational time. The material properties corresponding to the Aluminum 2024-T3 specimen were considered (73.1 GPa Young's modulus, 0.33 Poisson's ratio, and 2780 kg/m³). The element chosen for the specimen was structural solid element SOLID45. For eliminating the reflections from the boundaries of the plate, 30 mm non-reflective boundaries (NRB) were applied at the edges of the model using the spring-damper element COMBIN14 in ANSYS®. The application of NRB at the boundaries is presented in FIG. 1.

FIG. 2A represents, for an M₁₁ moment tensor excitation applied at a crack tip as the crack growth excitation, the top view of the M₁₁ moment excitation generated using dipole forces (F1). FIG. 2B represents a thickness view of the M₁₁ moment excitation associated with FIG. 2A, while FIG. 2C illustrates waveform of smooth step excitation, and FIG. 2D illustrates frequency spectrum of such smooth step excitation associated with FIG. 2C.

Finite element meshing was performed by selecting a ⅓ mm element size for the length and thickness of the model. The fatigue crack growth source modeling due to a crack growth event was modeled using the dipole moment excitation concept. In this modeling, the AE source due to a fatigue crack growth event was considered as self-equilibrating dipole forces acting at the crack tip. In previous research, this source definition has been implemented for fatigue crack growth AE numerical prediction and sensing using a PWAS sensor and validated using experimental investigation. ^{[11]} The M₁₁ dipole excitation was modeled in the FEM by using dipole forces. The modeling details of the dipole force are presented in FIGS. 2A-2D. FIG. 2A represents the top view of the dipole excitation on the meshed geometry and the thickness view of the dipole excitation is given in FIG. 2B. Equal and opposite nodal forces were applied to define the M₁₁ dipole excitation. A cosine-bell function excitation was applied as the time profile of the excitation with 0.5 μs as the rise time of the excitation. The waveform and frequency spectrum are shown in FIG. 2C and FIG. 2D, respectively. The finite element simulation was performed to obtain the acoustic waveforms generated due to the M₁₁ excitation for various crack lengths.

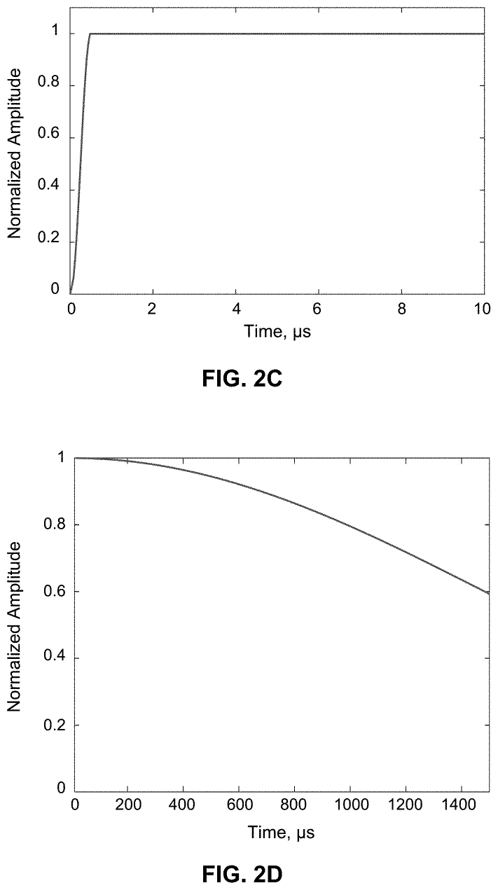

After the calculation, the surface strain (εₓₓ and ε_{yy}) captured by a PWAS sensor was extracted from FEM simulation to study wavefield pattern due to fatigue crack growth. The wave propagation pattern resulting from the excitation is presented in FIGS. 3A and 3B. FIGS. 3A and 3B illustrate a wave propagation pattern of surface strain (εₓₓ and ε_{yy}) due to M₁₁ excitation. FIG. 3A represents the wave propagation pattern in a non-cracked specimen, and FIG. 3B shows the wave propagation pattern in an 8 mm crack specimen. It was found that even though the excitation was the same for all simulations, the wave propagation patterns differ due to the existence of crack. This difference is due to the resonance of AE signals originating at the crack. AE energy generated at one crack tip travels to the other tip and establishes a standing wave pattern that has a characteristic dominant frequency which depends on the crack length. This causes some additional resonance and acts as an additional wave source causing the difference in AE wave propagation pattern compared to the non-cracked situation.

FIGS. 3A and 3B illustrate a wave propagation pattern of surface strain (εₓₓ+ε_{yy}) due to M₁₁ excitation, with FIG. 3A representing no crack, and FIG. 3B representing an 8 mm crack.

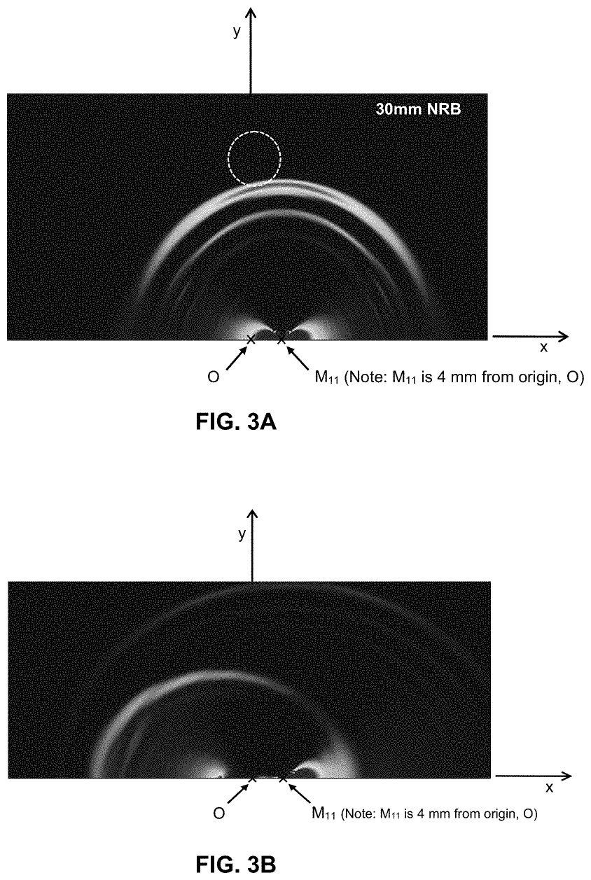

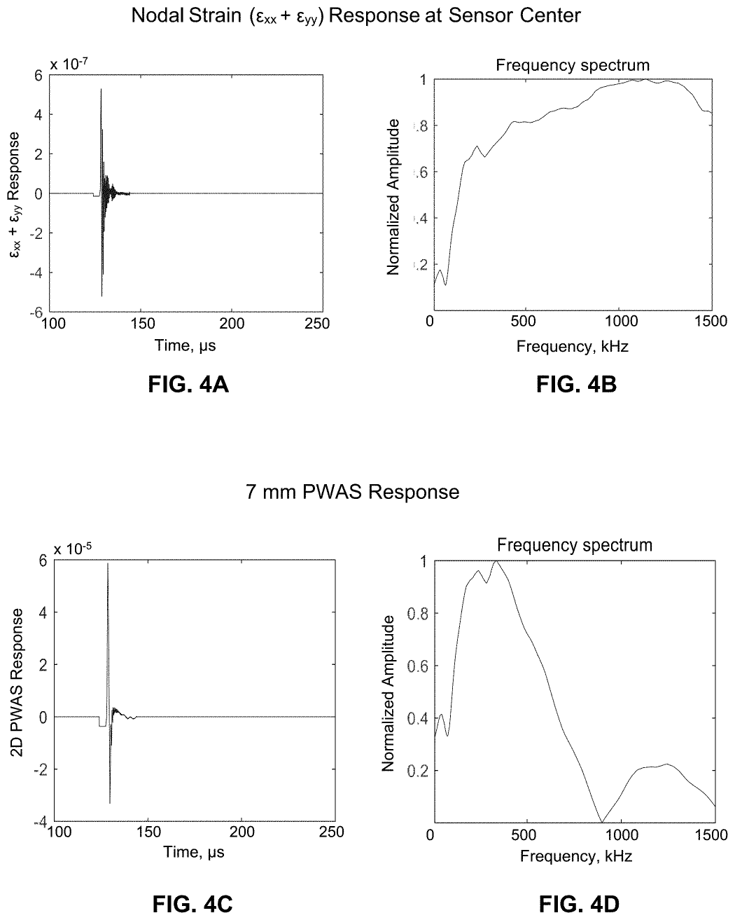

We have seen that the crack length affects the wave propagation pattern due to an AE event. If the difference can be observed in the wavefield pattern, the AE signals sensed using a finite-size sensor should have some differences. For identifying the effect of AE signals due to the presence of crack on an AE signal sensed using a finite-size PWAS, the signals sensed using a 7-mm diameter PWAS sensor for 4 mm, 6 mm, and 8 mm crack length were studied. The PWAS sensor senses the in-plane strain of the AE signal. The voltage sensed using a PWAS sensor was calculated through the area integral of in-plane strain. The PWAS was assumed to be bonded at 25 mm from the crack center as presented in FIG. 1. The εₓₓ and ε_{yy} of the AE signal at the nodes where the PWAS is located are obtained from the FEM simulation. The nodal strain data were integrated numerically, and the resulting PWAS sensor response was calculated. The PWAS response was evaluated for cases of no crack, 4 mm crack, 6 mm crack, and 8 mm crack. The nodal strain response and the numerically calculated PWAS response for the no crack case are presented in FIGS. 4A-4D. For the 4 mm crack, 6 mm crack, and 8 mm crack, the nodal response and resulting PWAS response are presented in FIGS. 5A-5D, FIGS. 6A-6D, and FIGS. 7A-7D, respectively. As we observed from FIGS. 4A-4D, FIGS. 5A-5D, FIGS. 6A-6D, and FIGS. 7A-7D, the nodal response is modified by the PWAS according to the tuning curve corresponding to the dimensions of the PWAS. The effect of the PWAS tuning curve caused the AE signal nodal response peaks to be weakened. The nodal response has specific peaks and valleys in its frequency spectrum for various crack lengths. The important point to be noted here is, up to 1500 kHz, the 4 mm crack has 2 peaks in the frequency spectrum; the 6 mm crack gives 3 peaks in the frequency spectrum. In the case of 8 mm crack length, the nodal AE signal frequency spectrum has 4 peaks. The crack length and peaks in the frequency spectrum of the AE signal have a proportional relation. This is also observed in the peaks of integrated effect due to the finite-size 7 mm PWAS, with only the weakening effect of the peaks at higher frequencies. This proportional increment in the peaks in the frequency spectrum of the signal is due to the change in the resonance of the AE signal at the crack. With the change in the crack length, the change in the resonance of the AE signal at the crack happens, which is causing the variation in the frequency spectrum peak valley pattern at the PWAS.

FIGS. 4A-4D illustrate FEM simulation AE signals of no-crack case, with FIG. 4A illustrating nodal in-plane strain response of AE signal at PWAS sensor center, with FIG. 4B illustrating frequency spectrum of nodal in-plane strain response at PWAS sensor center, with FIG. 4C illustrating 7 mm PWAS response of AE signal at 25 mm from origin, and with FIG. 4D illustrating frequency spectrum of 7 mm PWAS response of AE signal at 25 mm from origin.

FIGS. 5A-5D illustrate FEM simulation AE signal of 4 mm crack case, with FIG. 5A illustrating nodal in-plane strain response of AE signal at PWAS sensor center, with FIG. 5B illustrating frequency spectrum of nodal in-plane strain response, with FIG. 5C illustrating 7 mm PWAS response of AE signal at 25 mm from crack center, and with FIG. 5D illustrating frequency spectrum of 7 mm PWAS response.

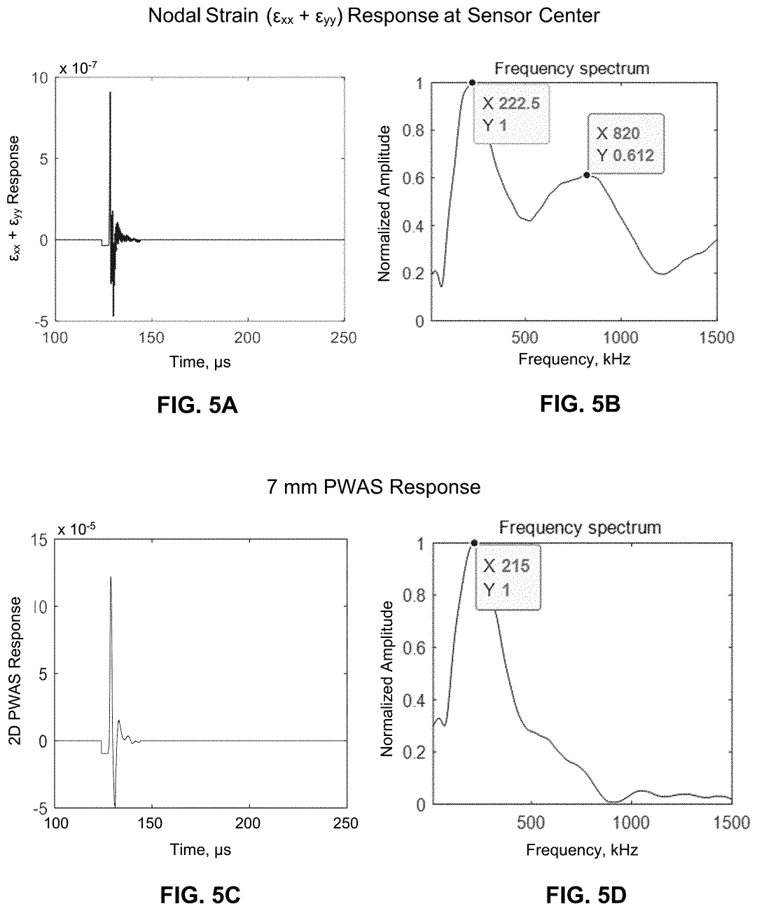

FIGS. 6A-6D illustrate FEM simulation AE signal of 6 mm crack case, with FIG. 6A illustrating nodal in-plane strain response of AE signal at PWAS sensor center, with FIG. 6B illustrating frequency spectrum of nodal in-plane strain response, with FIG. 6C illustrating 7 mm PWAS response of AE signal at 25 mm from crack center, and with FIG. 6D illustrating frequency spectrum of 7 mm PWAS response.

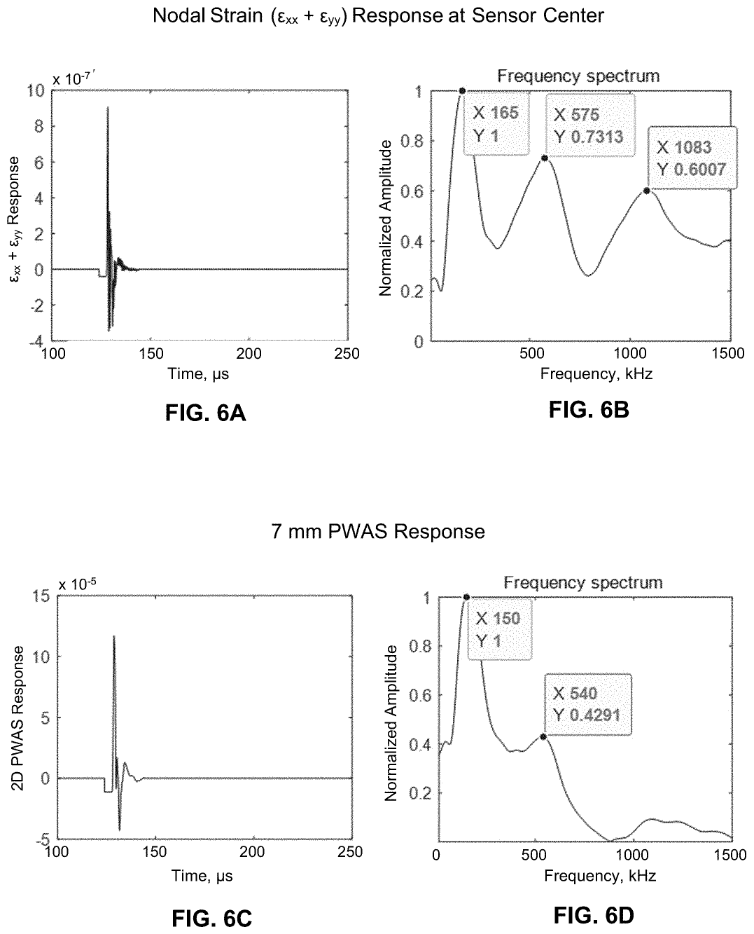

FIGS. 7A-7D illustrate FEM simulation AE signal of 8 mm crack case, with FIG. 7A illustrating nodal in-plane strain response of AE signal at PWAS sensor center, with FIG. 7B illustrating frequency spectrum of nodal in-plane strain response, with FIG. 7C illustrating 7 mm PWAS response of AE signal at 25 mm from crack center, and with FIG. 7D illustrating frequency spectrum of 7 mm PWAS response.

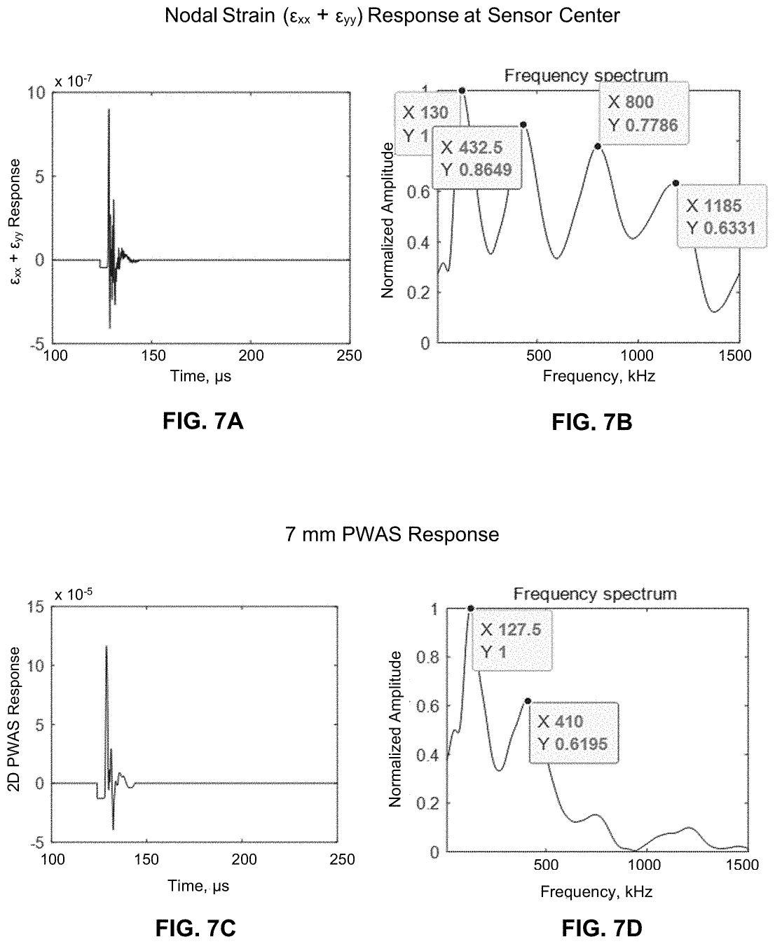

FIGS. 8A-8D illustrate spectrum of AE signals in 1 mm aluminum plate with various crack lengths, with FIG. 8A illustrating no crack, with FIG. 8B illustrating with 4 mm crack, with FIG. 8C illustrating with 6 mm crack, and with FIG. 8D illustrating with 8 mm crack (and for all with the frequency of spectrum peaks directly related to crack length). Thus, FIGS. 8A-D show frequency spectra of AE signals for various crack lengths. It was found that the surface strain (εₓₓ and ε_{yy}) values measured at the node corresponding to the center of the PWAS sensor were observed to have a peak-and-valley pattern in the frequency spectrum. The location of peaks and valleys in the frequency spectrum was observed to have a proportional relation to the crack length. The frequency of spectrum peaks is directly related to crack length.

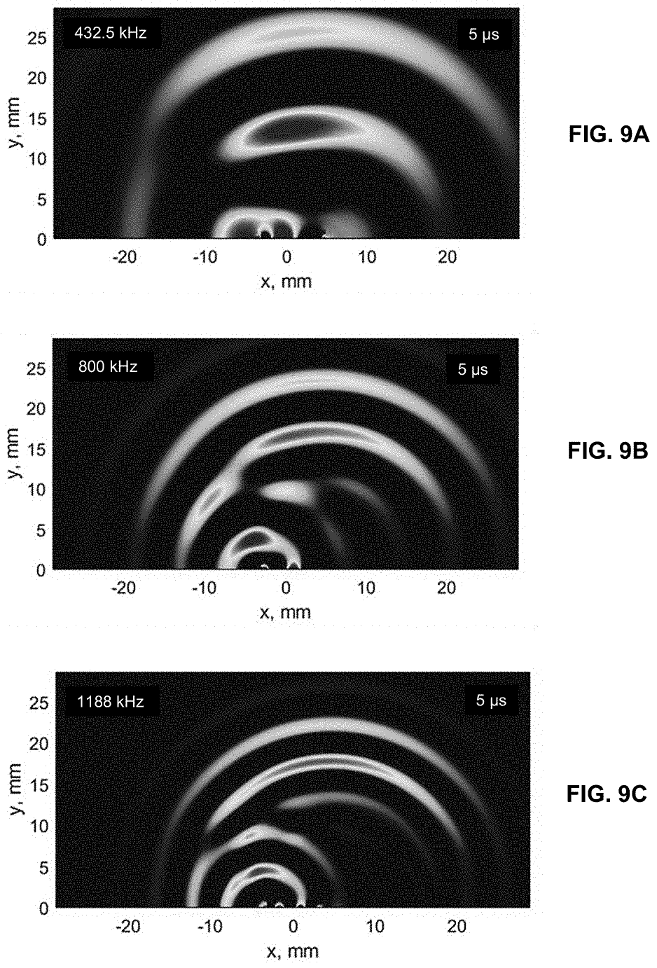

In order to further analyze the wavefield for 8 mm crack response, the wavefields at various peak frequencies were extracted from the total wavefield through the peak frequency filter to analyze crack length related resonant frequency. FIG. 10 shows the extracted wavefields for the 8 mm crack response. It was found that the wavelength decreases as the frequency increases. Additional waves generated at another crack tip were observed.

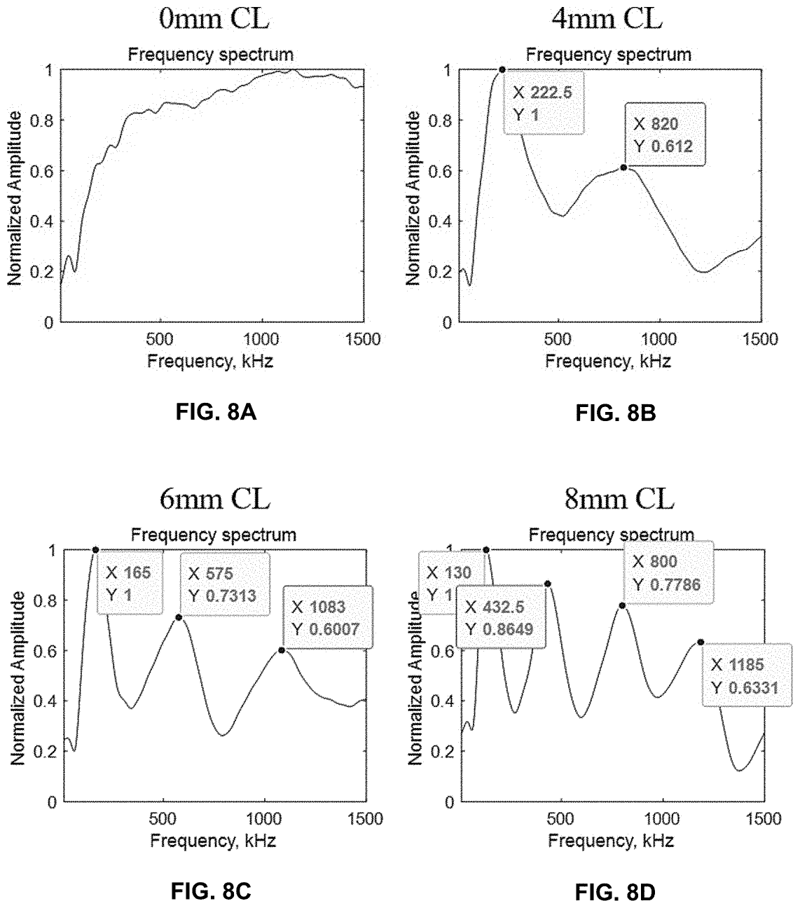

FIGS. 9A-9C illustrate wavefields at various peak frequencies for 8 mm crack response, including at 432.5 kHz (FIG. 9A), 800 kHz (FIG. 9B), and 1188 kHz (FIG. 9C).

### Example 2

An AE experimental specimen was designed for capturing AE during crack growth in thin metallic plates. Aluminum 2024-T3, a commonly used aircraft material, was chosen for preparing the test specimens. From a large plate of Aluminum 2024-T3, coupons of 103 mm width, 305 mm length, and 1 mm thickness were machined using the shear metal cutting machine. Specimens were sufficiently wide enough to allow a long crack to form in the specimen. Fatigue cyclic loading was performed on the specimen by applying fatigue load ranging from 13.85-1.38 kN at 10 Hz. A fatigue crack was originated from the 1 mm hole at the specimen center due to the continuous fatigue loading. The tip-to-tip crack length was 4 mm at 322 kcycles of fatigue loading.

FIG. 10 illustrates an AE test specimen bonded with the two PWAS and two S9225 sensors. NRB were provided on the specimen to avoid the reflection of AE signals from the specimen boundaries.

When the crack initiation happened, the specimen was taken out of the MTS machine. The sensors were installed, and an NRB was implemented on the specimen. The NRB was applied to the specimen to reduce AE signal reflections from the plate boundaries and thus to receive reflection-free and clean AE signals. After the AE sensor and NRB implementation on the specimen (FIG. 10), the crack was grown an additional 5.4 mm (until the crack length reached 9.4 mm tip to tip), simultaneously capturing the AE signals. The specimen's wide geometry was desired for this work so that the acoustic waves generated would travel a longer distance to the edges. This hypothesis, in turn, means the signals die out after reflection from the boundaries due to geometric spreading and material damping before reaching the sensors.

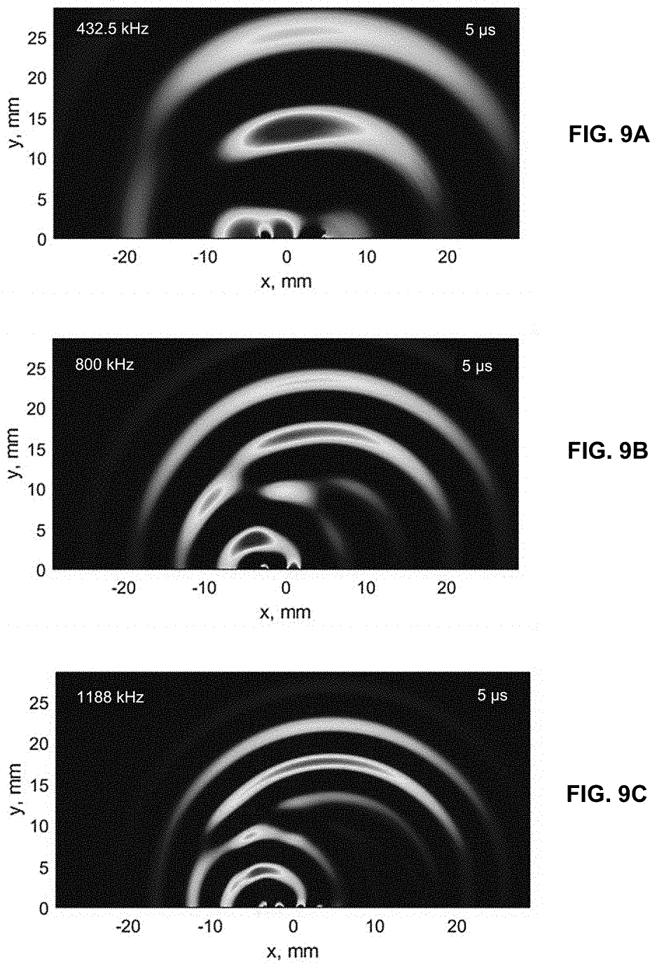

The test specimen installed with PWAS and S9225 transducers was mounted on the MTS machine (FIG. 10). The experimental/demonstration setup for capturing the AE signal from a fatigue crack growth event is presented in FIGS. 11A and 11B. The bond quality assurance of PWAS sensors was performed periodically by electromechanical impedance spectroscopy (EMIS). AE signals during crack growth events were captured by using PWAS and S9225 sensors. The sensors were connected to the acoustic preamplifier. The acoustic preamplifier is a bandpass filter that filters out signals between 30 kHz and 700 kHz, provided with 20/40/60 dB gain (can be selected using a switch). In the present experiment, 40 dB gain was selected. The preamplifier was connected to the MISTRAS AE system. A sampling frequency of 10 MHz was chosen to capture any high-frequency AE signals. The timing parameters set for the MISTRAS system were: peak definition time (PDT)=200 μs, hit definition time (HDT)=800 μs, and hit lockout time (HLT)=1000 μs.

FIG. 11A illustrates a schematic of an experimental/demonstration setup for performing fatigue testing with AE capturing. FIG. 11B illustrates equipment and connections for an experimental/demonstration setup for performing fatigue testing with AE capturing, as schematically illustrated in FIG. 11A.

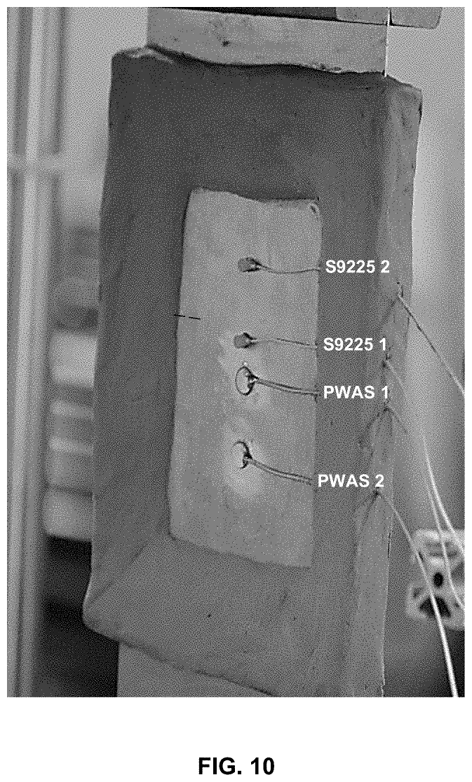

FIGS. 12A and 12B illustrate a comparison between FEM simulation results of crack-related AE signals (FIG. 12A) vs. experimental AE CWT plots captured in stress intensity factor (SIF)-controlled fatigue scenario (FIG. 12B).

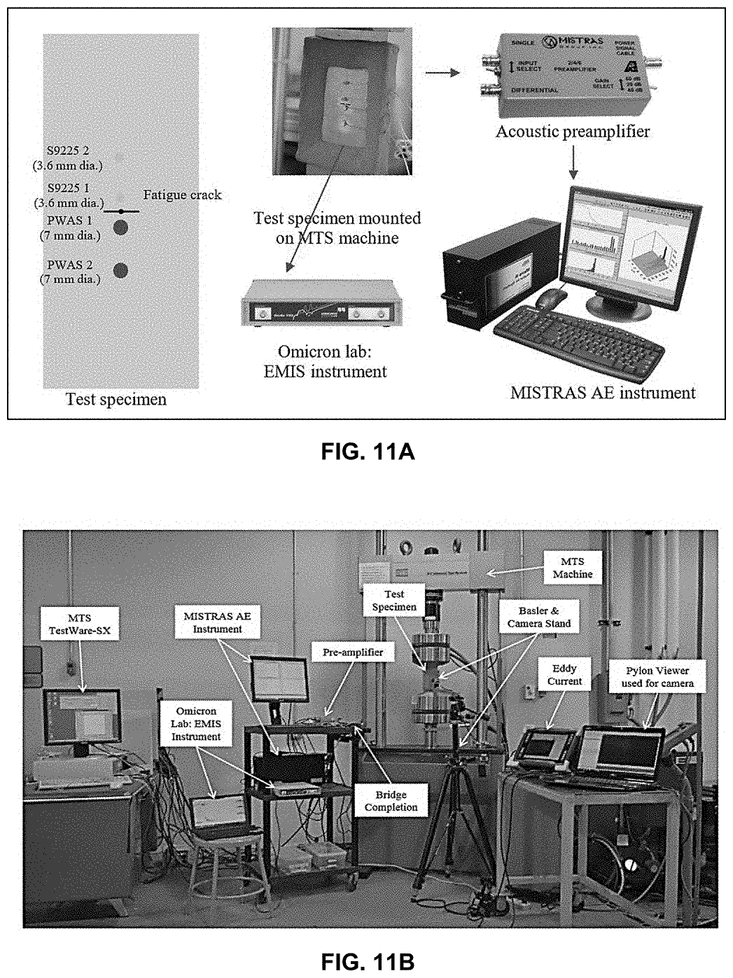

A comparison of the AE signal at 8 mm crack length is presented in FIGS. 12A and 12B and FIGS. 13A and 13B. FIGS. 13A and 13B illustrate a comparison between FEM simulation results of crack-related AE signals (FIG. 13A) vs. experimental AE waveforms captured in SIF-controlled fatigue scenario (FIG. 13B). FIGS. 13A and 13B present the time domain of the AE signal for 8 mm crack. A fast Fourier transform of the experimental AE signal was performed to obtain the frequency spectrum of the signal. At 8 mm crack length, two major peaks in the frequency spectrum were observed in the experimental frequency spectrum. We also observe two major peaks in the frequency spectrum of the FEM simulation signal as well. As we observe from the simulation, the AE signal originating at the crack tip resonates at the crack before reaching the AE sensor. The AE signal resonates differently for 4 mm and 8 mm crack length cases. This causes the difference in the peak valley pattern in the frequency spectrum of the AE signal. Thus, using this novel approach, the frequency spectrum of the AE signal recorded using PWAS can be used to find the fatigue crack length approximately from the AE signal recorded during fatigue crack growth. The AE signals resonate depending on the length of the crack, which causes the peak valley pattern in the frequency spectrum of the AE signal.

FIGS. 13A and 13B illustrate a comparison between FEM simulation results of crack-related AE signals (FIG. 13A) vs. experimental AE waveforms captured in SIF-controlled fatigue scenario (FIG. 13B).

### Example 3

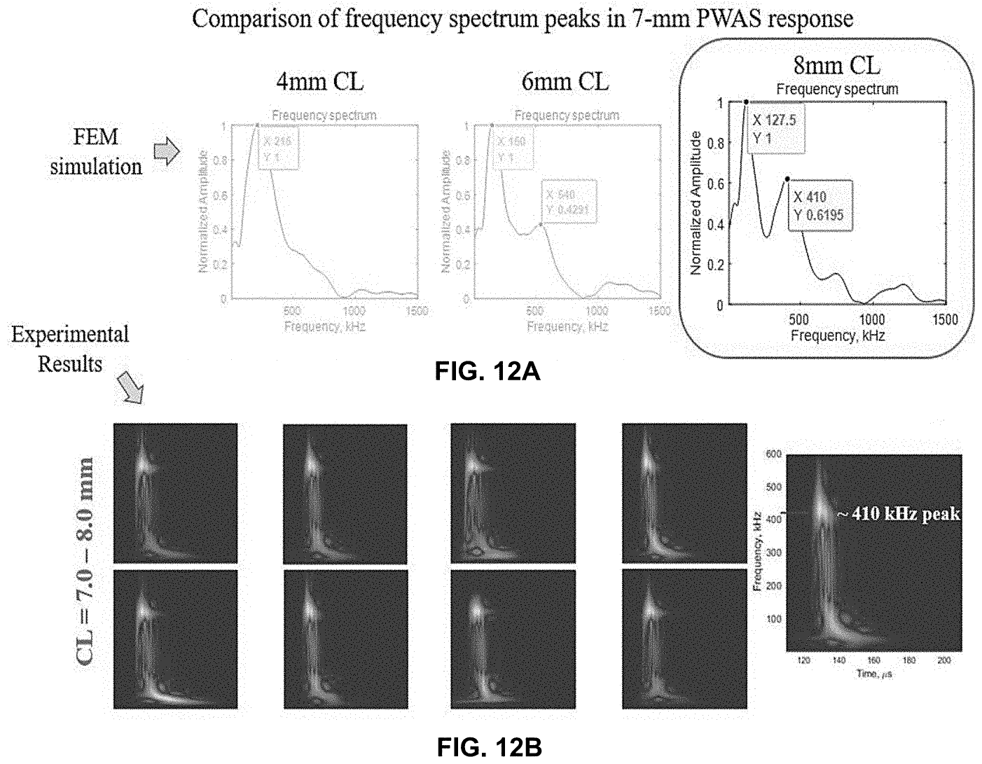

In this presently disclosed subject matter, AlexNet CNN was chosen as an example to study the crack length estimation from AE signals using artificial intelligence. The proposed method is not limited to AlexNet; it is simply a generic example. We can use existing or to-be-developed neural network architectures to achieve the crack length estimation. The general concept of the neural networks follows the standard multilayer perception model which involves appropriately training its neural connections by backpropagating error and adjusting connection weights following standard steepest gradient descent. FIG. 14 shows the model of a deep neural network which includes multiple hidden layers of nodes, each connected to the nodes of previous and ensuing layers by weighting factors.

FIG. 14 illustrates a schematic of a multilayer perception artificial neural network model as presently referenced.

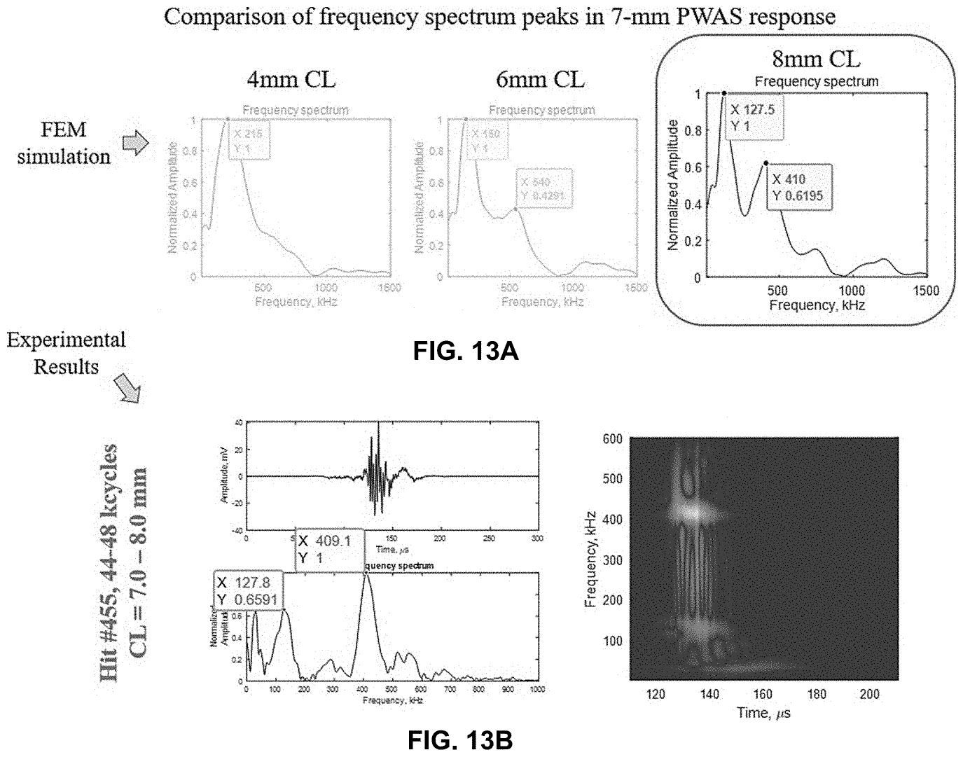

For AlexNet, an image recognition CNN, images of input size 227×227 pixel are required. To adopt the experimental AE signals to this criterion, the CWT of the AE waveforms was processed to generate an intensity plot yielding information about the time domain and frequency domain of the AE wave, simultaneously. This intensity plot is then augmented to conform to the 227×227-pixel requirement before being used as input by the neural network. A schematic of this process is given in FIG. 15.

FIG. 15 illustrates a CWT of the AE signals cropped and augmented to fit the 227×227-pixel criteria before being entered into the input layer of the AlexNet CNN architecture.

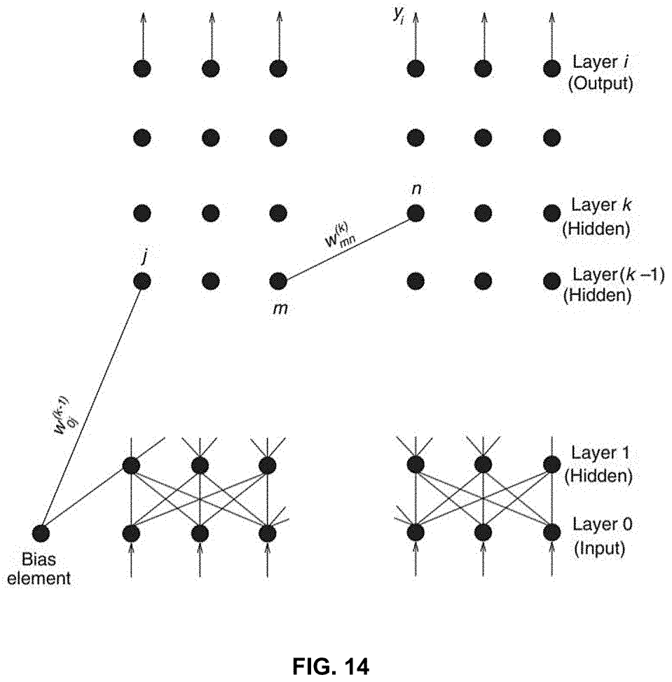

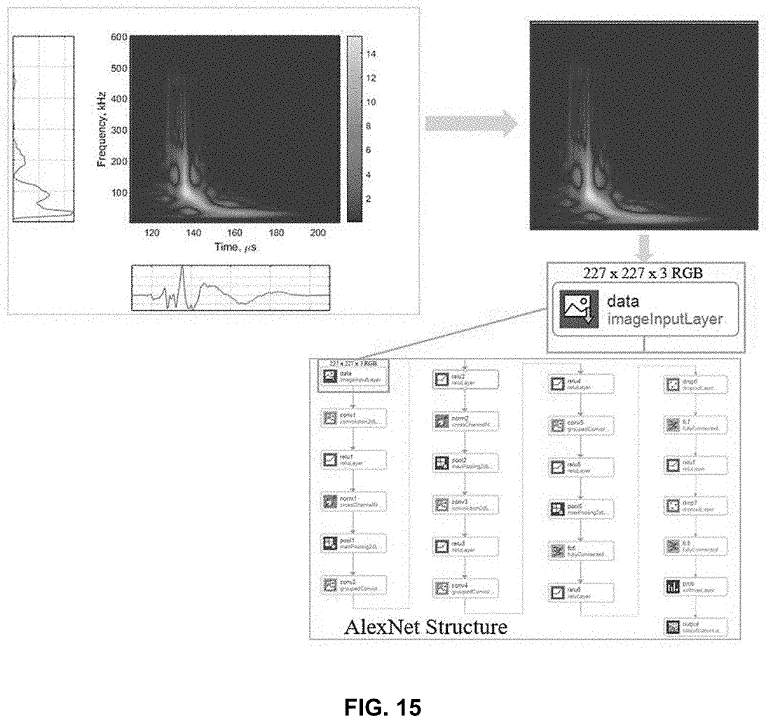

To build the related CNN for crack length prediction, AE signals were used from the experiment described in the previous section. Here, signals were obtained from the far-field PWAS2 during the experiment when the crack was in the ranges of 3.5-4.5 mm and 7.0-8.0 mm in total length. As previously described, the fundamental concept is that these AE signals will differ in various characteristics, specifically in the frequency domain. The goal is to build an AI system capable of discerning these distinctions and accurately predicting the crack length from the AE signal. FIG. 16 shows a schematic of the sensing of the two distinct groups of AE signals used to build an example crack length estimation CNN. In FIG. 17, a few examples of the experimental signal CWTs for each of the groups are shown. To train the network, 28 hits from the 3.4-4.5 mm range and 137 hits from the 7.0-8.0 mm range were used as the input training dataset. The significant difference in the number of signals from the two groups was a result of more AE signals being captured while the crack was in the 7.0-8.0 mm range.

FIG. 16 illustrates a schematic of signals from different crack lengths usable to train AlexNet CNN for crack length recognition.

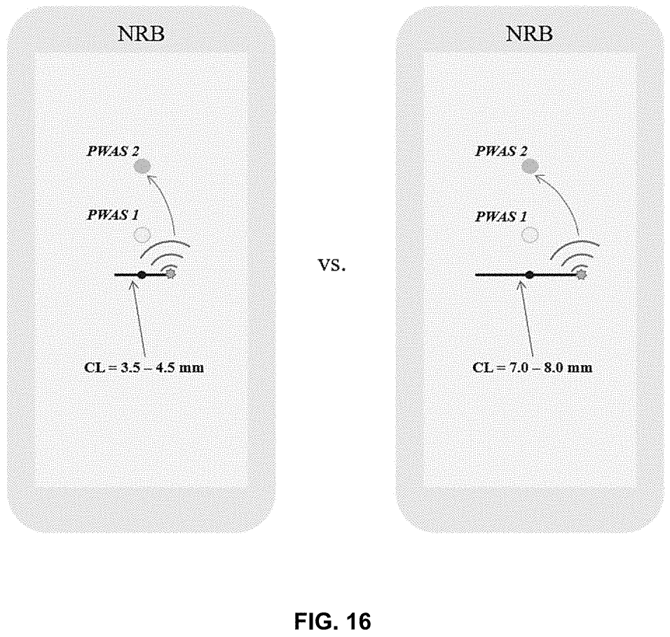

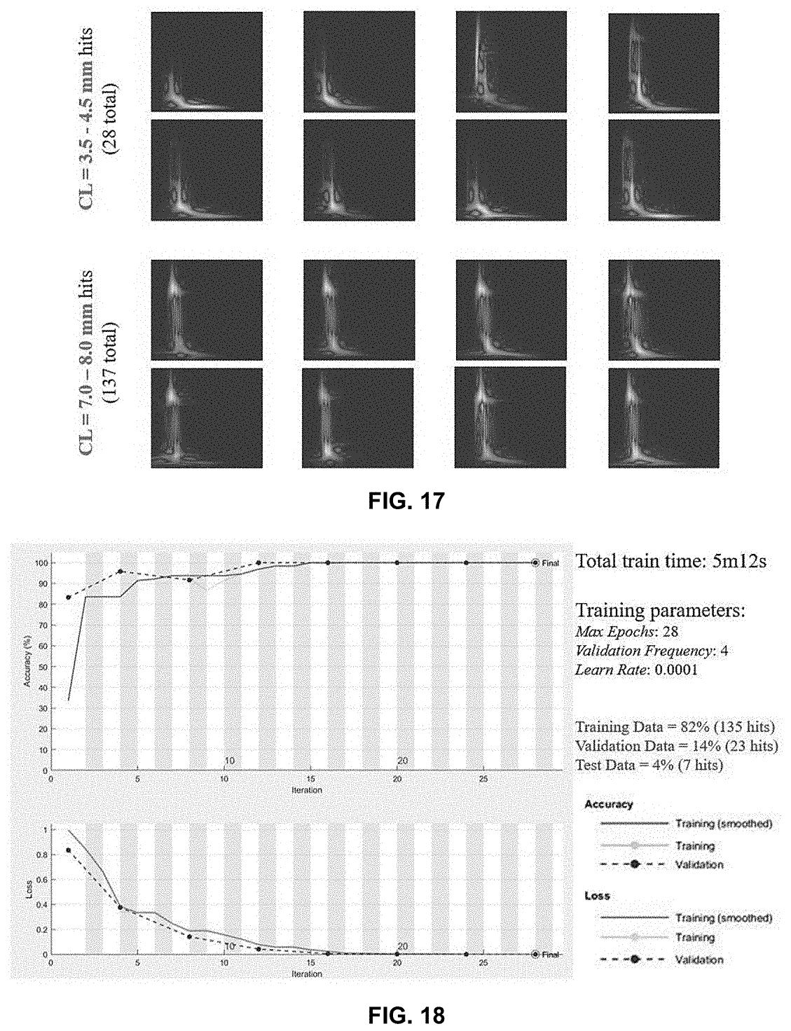

FIG. 17 illustrates example CWT figures used in crack length recognition AlexNet CNN. The dataset was split programmatically by the network training into subsets of 82% (135 hits) training data, 14% (23 hits) validation data, and 4% (7 hits) system test data. Significant training parameters were optimally selected based on experience. The max epochs was set to 28, the validation frequency was set to 4, and the learning rate was set to 0.0001. FIG. 18 shows the training progress of the network. The network took a total of 5 minutes and 12 seconds to train completely, at which point exceptional convergence was reached. After the network was sufficiently trained, a manual test dataset of 86 new signals was presented to the network for classification. The results showed 98.8% network prediction accuracy, correctly predicting the crack length of 85 out of the 86 signals. FIGS. 19A and 19B show the confusion matrix of this manual network accuracy test, as well as the very noisy signal that was misclassified by the network.

FIG. 18 illustrates training progress of crack length recognition AlexNet CNN. FIGS. 19A and 19B illustrate manual network test results showing 98.8% classification accuracy (FIG. 19A) and noisy misclassified AE hit #114 from 44-48 fatigue kcycles (FIG. 19B).

The presently disclosed subject matter could be used for several applications, including, but not limited to, the following:
Rapid, remote, and real-time monitoring of fatigue crack growth in sheet metal structures
Identification of AE signals due to crack growth and discarding of AE signals not related to crack growth
Extraction of crack size/length information from the AE signal features
Use of the AE signals to monitor crack growth and predict remaining useful life
While certain embodiments of the disclosed subject matter have been described using specific terms, such description is for illustrative purposes only, and it is to be understood that changes and variations may be made without departing from the spirit or scope of the subject matter.

### REFERENCES

[1] T. M. Roberts and M. Talebzadeh, “Acoustic emission monitoring of fatigue crack propagation,” J. Constr. Steel Res., vol. 59, no. 6, pp. 695-712, June 2003, doi: 10.1016/S0143-974X(02)00064-0.
[2] T. M. Morton, R. M. Harrington, J. G. Bjeletich, L. Palo, and P. Alto, “Acoustic emissions of fatigue crack growth,” Eng. Fract. Mech., vol. 5, pp. 691-697, 1973.
[3] S. Deschanel, W. Ben Rhouma, and J. Weiss, “Acoustic emission multiplets as early warnings of fatigue failure in metallic materials,” Sci. Rep., no. September, pp. 1-10, 2017, doi: 10.1038/s41598-017-13226-1.
[4] T. M. Roberts and M. Talebzadeh, “Fatigue life prediction based on crack propagation and acoustic emission count rates,” J. Constr. Steel Res., vol. 59, no. 6, pp. 679-694, June 2003, doi: 10.1016/50143-974X(02)00065-2.
[5] A. Keshtgar and M. Modarres, “Acoustic emission-based fatigue crack growth prediction,” 2013 Proc. Annu. Reliab. Maintainab. Symp. (RAMS), Orlando, Fla., pp. 1-5, 2013.
[6] Y. Shen, J. Wang, and W. Xu, “Nonlinear features of guided wave scattering from rivet hole nucleated fatigue cracks considering the rough contact surface condition,” Smart Mater. Struct., vol. 27, no. 10, pp. 1-15, 2018.
[7] L. Zhang, D. Ozevin, W. Hardman, and A. Timmons, “Acoustic Emission Signatures of Fatigue Damage in Idealized Bevel Gear Spline for Localized Sensing,” Metals (Basel)., 2017, doi: 10.3390/met7070242.
[8] M. Y. Bhuiyan and V. Giurgiutiu, “The signatures of acoustic emission waveforms from fatigue crack advancing in thin metallic plates,” Smart Mater. Struct., vol. 27, no. 1, p. 15019, 2018, doi: 10.1088/1361-665X/aa9bc2.
[9] Y. Bhuiyan, J. Bao, and B. Poddar, “Toward identifying crack length-related resonances in acoustic emission waveforms for structural health monitoring applications,” Struct. Heal. Monit., vol. 17, no. 3, pp. 577-585, 2018, doi: 10.1177/1475921717707356.
[10] M. Y. Bhuiyan and V. Giurgiutiu, “Experimental and Computational Analysis of Acoustic Emission Waveforms for SHM applications,” in 11th International Workshop on Structural Health Monitoring, 2017, pp. 1-7.
[11] R. Joseph and V. Giurgiutiu, “Analytical and experimental study of fatigue-crack-growth ae signals in thin sheet metals,” Sensors (Switzerland), vol. 20, no. 20, pp. 1-25, 2020, doi: 10.3390/s20205835.

What is claimed is:

1. A computing system, comprising:
one or more processors; and
one or more non-transitory computer-readable media that collectively store:
a machine-learned Artificial Intelligence (AI)-enabled technology neural network architecture model configured to receive Acoustic Emission (AE) data sensed from a structure and to predictively model Structural Health Maintenance (SHM) of the structure; and
instructions that, when executed by the one or more processors, configure the computing system to perform operations, the operations comprising:
obtaining detected AE data from sensors used with an associated structure to be monitored;
inputting the AE data into the machine-learned neural network architecture model;
determining a characteristic dominant frequency of a standing wave pattern resulting from AE energy generated at one crack tip and traveling to the other crack tip of a crack formed in the monitored structure; and
as an output of the machine-learned neural network architecture model, determining the crack length of the crack generating the AE data.

2. A computing system according to claim 1, wherein the one or more processors are further configured so that the determining operations include detecting peaks in a detected frequency spectrum that shift as crack length changes.

3. A computing system according to claim 2, wherein the one or more processors are further configured so that the machine-learned AI-enabled technology neural network architecture model learns to predict crack length directly from individual AE data signals, for estimating in real-time the crack length information from the high-frequency AE waveforms during fatigue crack growth.

4. A computing system according to claim 3, wherein the one or more processors are further configured so that the machine-learned AI-enabled technology neural network architecture model estimates fatigue crack length in sheet metal structures using the information contained in the high-frequency AE signal signatures.

5. A computing system according to claim 3, wherein the one or more processors are further configured so that the machine-learned AI-enabled technology neural network architecture model uses physics-based modeling to generate synthetic datasets for training AI algorithms.

6. A computing system according to claim 5, wherein the one or more processors are further configured so that the machine-learned AI-enabled technology neural network architecture model comprises finite element modeling (FEM) simulation conducted to identify the correlation between AE signal and crack length during a fatigue crack growth event.

7. A computing system according to claim 6, wherein the one or more processors are further configured so that the machine-learned AI-enabled technology neural network architecture model comprises fatigue crack growth source modeling due to a crack growth event modeled using the dipole moment excitation concept.

8. A computing system according to claim 7, wherein the fatigue crack growth event was considered as self-equilibrating dipole forces acting at the crack tip.

9. A computing system according to claim 8, wherein the one or more processors are further configured so that, after dipole force calculation, the surface strain (εₓₓ and ε_{yy}) captured by a PWAS sensor is extracted from FEM simulation so that the machine-learned AI-enabled technology neural network architecture model learns wavefield patterns due to fatigue crack growth.

10. A computing system according to claim 5, wherein the one or more processors are further configured so that the machine-learned AI-enabled technology neural network architecture model uses finite element modeling using the moment tensor concept for achieving prediction of how crack length values affect the high-frequency content of AE signals.

11. A computing system according to claim 5, wherein the one or more processors are further configured so that the machine-learned AI-enabled technology neural network architecture model uses adaptation of the three-dimensional (3D) moment-tensor concept from geophysics to apply to the prediction of AE signals in thin-plates using guided-wave theory.

12. A computing system according to claim 3, wherein the one or more processors are further configured so that the machine-learned AI-enabled technology neural network architecture model determines a proportional relation between the crack length and peaks in the frequency spectrum of the AE signal.

13. A computing system according to claim 3, wherein the one or more processors are further configured so that the machine-learned AI-enabled technology neural network architecture model uses AE signals to monitor crack growth and predict remaining useful life of the monitored structure.

14. A computing system according to claim 3, wherein the one or more processors are further configured so that the machine-learned AI-enabled technology neural network architecture model is tuned so that predictive AE models achieve similarity to experimentally observed AE signals.

15. A computing system according to claim 14, wherein the one or more processors are further configured so that the machine-learned AI-enabled technology neural network architecture model makes selection of representative AE signal features in time domain and frequency domain to enable tuning of the predictive AE models.

16. A computing system according to claim 3, wherein the one or more processors are further configured so that the machine-learned AI-enabled technology neural network architecture model sifts through large experimental AE signals datasets to identify dominant trends correlated with crack length information.

17. A computing system according to claim 16, wherein the machine-learned AI-enabled technology neural network architecture model comprises an AlexNet convolutional neural network (CNN).

18. A computing system according to claim 17, wherein the one or more processors are further configured so that a Choi-Williams transform of the acoustic emission signals is cropped and augmented to fit 227×227-pixel criteria before being entered into an input layer of the AlexNet convolutional neural network architecture.

19. A computing system according to claim 16, wherein the machine-learned AI-enabled technology neural network architecture model comprises neural network architecture following a standard multilayer perception model for training its neural connections by backpropagating error and adjusting connection weights following standard steepest gradient descent.

20. A computer-implemented method, comprising:
obtaining, by a computing system comprising one or more computing devices, detected Acoustic Emission (AE) data from sensors used with an associated structure to be monitored;
inputting, by the computing system, the detected AE data into a machine-learned neural network architecture model configured to receive AE data sensed from a structure and to predictively model Structural Health Maintenance (SHM) of the structure;
receiving, by the computing system, as an output of the machine-learned neural network architecture model, a characteristic dominant frequency of a standing wave pattern resulting from AE energy generated at one crack tip and traveling to the other crack tip of a crack formed in the monitored structure; and
determining, by the computing system, the crack length of the crack generating the AE data.

21. A computer-implemented method according to claim 20, further comprises determining maintenance activities for the monitored structure based on determined crack lengths.
